(19) United States
(12) Patent Application Publication
(10) Pub. No.: US 2010/0221894 A1
(43) Pub. Date: Sep. 2, 2010

(54) METHOD FOR MANUFACTURING NANOWIRES BY USING A STRESS-INDUCED GROWTH

(75) Inventors: Woo Young Lee, Seoul (KR); Jin Hee Ham, Seoul (KR); Woo Young Shim, Seoul (KR); Jong Wook Roh, Seoul (KR); Seung Hyun Lee, Seoul (KR); Kye Jin Jeong, Suwon (KR)

Correspondence Address: LEXYOUME IP GROUP, LLC, 5180 PARKSTONE DRIVE, SUITE 175, CHANTILLY, VA, 20151, US

(73) Assignee: Industry-Academic Cooperation Foundation, Yonsei University, Seoul (KR)

(21) Appl. No.: 12/064,861

(22) PCT Filed: Dec. 28, 2006
(86) PCT No.: PCT/KR07/06944

§ 371 Date: Feb. 26, 2008

(30) Foreign Application Priority Data
Dec. 28, 2006 (KR) 10-2006-0137069
May 28, 2007 (KR) 10-2007-0051236

(51) Int. Cl. H01L 21/20

(52) U.S. Cl. 438/478; 257/E21.09

(57) ABSTRACT

Provided is a method for manufacturing a nanowire using stress-induced growth. The method includes: providing a substrate with an intermediate layer formed thereon; forming thin film on the intermediate layer, wherein the thin film made of material having more than 2×10⁻⁶/° C. of thermal expansion coefficient difference from the intermediate layer; inducing tensile stress due to the thermal expansion coefficient difference between the thin film and the substrate by performing a heat treatment on the substrate with the thin film formed; and growing single-crystalline nanowire of the material by inducing compressive stress at the thin film through cooling of the substrate.

The present application claims priority under 35 U.S.C. 119 to Korean Patent Application No. 10-2006-137069 (filed on Dec. 28, 2006) and 10-2007-0051236 (filed on May 28, 2007), which are hereby incorporated by reference in their entirety.

### TECHNICAL FIELD

The present invention relates to a method for manufacturing a nanowire using stress-induced growth and, more particularly, to a method for manufacturing single-crystalline nanowire using compressive stress induced when heat treatment is performed on deposited thin film.

### BACKGROUND ART

Many researches have been made for semimetallic bismuth (Bi) due to advantageous transport properties thereof, such as anisotropic Fermi surface, long mean free path l, and small effective mass m*. Also, Bi has been receiving attention for understanding new physical phenomenon because finite size effect and semimetal-semiconductor phase transition were observed in Bi nanowire having diameter of 50 nm. Finite size effect is a phenomenon that the free path of a carrier is limited by the size of nanowire, and the semimetal-semiconductor phase transition is quantum confinement effect.

Although it is essential to manufacture single-crystalline nanowire for analyzing the characteristics of Bi nanowire, nanowire growth has been limited because it is difficult to have single crystallinity. Furthermore, not many methods for growing Bi nanowire have been known.

As known, BiₓTe₁₋ₓ, composition of semimetallic Bi and semiconductor Te, has large mass, and can reduce thermal conductivity due to Van der Waals bonding between Bi and Te and covalent bonding between Te atoms. Accordingly, BiₓTe₁₋ₓ can increase figure of merit (ZT). Owing to such advantageous characteristics thereof, BₓTe₁₋ₓ has been receiving attention as thermal conductive material.

By manufacturing nanowire using BₓTe₁₋ₓ which is a semiconductor material, it is possible to control electrical density of state. Also, it is possible to control Seebeck coefficient that influences thermoelectric effect if the shape and peak position of an energy level density function match to the Fermi level. And BiₓTe₁₋ₓ nanowire can sustain electric conductivity at high level by increasing electron-mobility through quantum confinement effects. Therefore, it is possible to obtain comparatively large ZT value by overcoming the limitation of bulk thermoelectric material.

Since single-crystalline nanowire is generally manufactured at high temperature, a typical method of manufacturing single-crystalline nanowire cannot be used for growing a Bi nanowire that has comparatively low melting point, for example, 271.3° C. In order to manufacture BiₓTe₁₋ₓ nanowire, it is necessary to grow the alloy of Bi and Te together instead of growing single material. Therefore, a solvent with necessary materials melted together was used to grow BiₓTe₁₋ₓ nanowire. As a method for manufacturing BiₓTe₁₋ₓ nanowire according to the related art, template-assisted method, solution-phase method, hydrothermal method, and solve-thermal method were introduced. However, template-assisted method has a difficulty for preparing templates. The other methods need starting materials and must perform complicated processes. Furthermore, it is necessary to remove template and residual chemical materials from nanowire surface. Also, it is difficult to form various patterns due to low aspect ratio when a module is manufactured based on the above methods. Most of all, there is a limitation to obtain advantageous properties of Bi and BiₓTe₁₋ₓ because Bi nanowire or BiₓTe₁₋ₓ nanowire is formed as polycrystalline if the Bi nano wire or the BiₓTe₁₋ₓ nanowire is manufactured by the above methods.

### DISCLOSURE

### Technical Problem

The present invention is proposed in order to provide a method for manufacturing single-crystalline nanowire without performing process for preparing templates or catalysts or without starting materials and phase transition of a base material to liquid or gaseous state.

### Technical Solution

According to the present invention, the method for manufacturing nanowire using compressive stress, includes:

providing a substrate;

forming thin film on the substrate, wherein the film is made of material having more than 2×10⁻⁶/° C. of thermal expansion coefficient difference from the substrate;

inducing tensile stress due to the thermal expansion coefficient difference between the thin film and the substrate by performing heat treatment on the substrate with the thin film formed; and

growing single crystalline nanowire of the material by inducing compressive stress at the thin film by cooling down the substrate.

The present invention uses difference between the thermal expansion coefficient of substrate and that of thin film deposited on the substrate. If the thermal expansion coefficient of the thin film is larger than that of the substrate, the thin film receives tensile stress when the substrate is heated. If the substrate coated with the thin film is cooled down after heating, the thin film receives compressive stress which is greater than that applied to the substrate because the thin film has thermal expansion coefficient larger than that of the substrate. The compressive stress operates as thermodynamic driving force that grows single crystalline nanowire from the thin film. As well as the thermal expansion coefficient difference, other factors may operate as the driving force that grows nanowire. For example, it is expected that strain caused by lattice mismatch may operate as the driving force. However, the stress generated by the difference of thermal expansion coefficients operates as the largest driving force among the stresses caused by other factors. The present invention utilizes this phenomenon.

Since the stress generated by the difference of the thermal expansion coefficients is released in a thickness direction of the thin film and the substrate if the thin film and the substrate are thick, the thickness of the thin film becomes a major variable. An intermediate layer may be formed between the substrate and the thin film because the substrate is excessively thicker than the thin film in general. Therefore, another embodiment has been proposed in order to provide a method for manufacturing nanowire as follows.

providing a substrate with an intermediate layer formed thereon;

forming thin film on the intermediate layer, wherein the thin film made of material having more than 2×10⁻⁶/° C. of thermal expansion coefficient difference from the intermediate layer;

inducing tensile stress due to the thermal expansion coefficient difference between the thin film and the substrate by performing a heat treatment on the substrate with the thin film formed; and

growing single crystalline nanowire of the material by inducing compressive stress at the thin film through cooling of the substrate.

Here, the thermal expansion coefficient difference between the substrate and the thin film may not be required to be large. However, the thermal expansion coefficient difference between the substrate and the intermediate layer should be large. The substrate may be a silicon substrate, and the intermediate layer may be an oxide layer.

Material consisting the thin film itself is the material for producing nanowire. That is, the thin film may be made of any material that can be grown as single crystalline nanowire by driving force provided as compressive stress. Since thermoelectric materials are the main concern in the present invention, the thin film made of bismuth or a binary alloy including bismuth is particularly preferred. The binary alloy may be formed of bismuth with one of Te, Sb, and Se. The alloy forms in a formation of BiₓA_{1-z} (A=Te, Sb, Se). Here, x preferably is 0.33 to 0.55. However, the present invention is not limited to the materials described above.

Although the method for depositing thin film is not limited to specific one, widely used sputtering is generally preferable. If the thin film material is a binary alloy, sputtering using the ally target or co-sputtering using single targets is preferable.

If the substrate is cooled down while performing sputtering, the grain size of thin film becomes smaller. As a result, it is possible to grow nanowire therefrom with smaller diameter.

Here, the intermediate layer should have sufficient thickness that can provide compressive stress for forming nanowire. Preferably the thickness of the intermediate layer is 3000 to 5000 Å. The thickness of the thin film is preferably limited to 10 nm to 4 μm. If the thickness of the thin film is thinner than 10 nm, the thin film may not have sufficient amount of material for growing nanowire. If the thickness of the thin film is thicker than 4 μm, the compressive stress of the intermediate layer becomes weaker than that required to grow nanowire and accordingly nanowire may not be grown enough.

As the heat treatment of the thin film, annealing at 100 to 1000° C. for 0.5 to 15 hours is preferable. If the temperature for the heat treatment is lower than 100° C., the thermal driving force is not provided to grow a nanowire. On the contrary, if the temperature is higher than 1000° C., the materials including the substrate can be damaged. If the annealing time is shorter than 0.5 hour, nanowire is not sufficiently grown. That is, 0.5 hour of annealing is insufficient to provide the thermodynamic driving force. As the thermal processing time increases, the thin film expands more, thereby generating more tensile stress. However, even if the annealing is performed longer than 15 hours, the stress is not generated any more.

As described above, nanowire is grown upwardly from the substrate. However, the growing direction may be controlled. If a barrier layer is deposited on the thin film to hider the nanowire from growing, the nanowire cannot be grown upwardly. In order to release compressive stress, the nanowire grows in lateral direction. The barrier layer is preferably made of SiO₂, Cr or W, although not limited thereto.

An oxide layer may be formed on the nanowire because the grown nanowire reacts with oxygen in the atmosphere. Therefore, a process for removing the oxide layer formed on the grown nanowire may be further performed for manufacturing a thermoelectric module using nanowire. Here, plasma etching is preferable. If the barrier layer is made of Cr in the method of manufacturing nanowire in lateral direction using the barrier layer, the nanowire grown in the lateral direction may be coupled to an electrode while heat treatment is performed. In this case, it is possible to fabricate the thermoelectric module without performing the process of removing oxide layer.

### Advantageous Effects

According to the manufacturing method for nanowire using compressive stress, it is not necessary to perform template preparing or catalyst preparing to grow single-crystalline nanowire. Furthermore, it is possible to grow single-crystalline nanowire with superior crystallinity without using starting material or hetero material or without phase transition to liquid state or gaseous state.

The single crystalline nanowire manufactured according to the present embodiment can be applied to various fields using thermoelectric modules, such as power generators for space, heaters, aeronautical heat controllers, military infrared IR detectors, missile guide circuit coolers, medical thermostats, and blood depositing devices.

Although the method of the present invention using compressive stress is particularly suitable for thermoelectric materials like Bi and BiₓTe₁₋ₓ it is not limited thereto. Therefore, various composition ratios of AₓB₁₋ₓ single crystalline nanowire can be grown with superior crystallinity.

### DESCRIPTIONS OF DRAWINGS

FIG. 1 is a schematic diagram illustrating the process for manufacturing single-crystalline nanowire according to present invention.

FIG. 2 is a diagram illustrating an apparatus for manufacturing single-crystalline nanowire according to present invention.

FIG. 3 is scanning electron microscopic (SEM) images of Bi and Bi₂Te₃ single crystalline nanowires, which are manufactured using the method of present invention.

FIG. 4 is transmission electron microscopic (TEM) images and electron diffraction pattern images of Bi and Bi₂Te₃ single crystalline nanowires, which are manufactured using the method of present invention.

FIG. 5 is a diagram illustrating results of element mapping and line scanning for the manufactured Bi₂Te₃ single crystalline nanowire.

FIG. 6 is a schematic diagram illustrating the growth of Bi or BiₓTe₁₋ₓ single crystalline nanowire.

FIG. 7 is a SEM image showing the dependency of diameter to thickness of thin film in Bi nanowire, which is manufactured using the method of present invention.

FIG. 8 is a graph showing dependency of diameter to thickness of thin film in Bi single crystalline nanowire, which is manufactured using the method of present invention.

FIG. 9 is a graph showing the dependency of BiₓTe₁₋ₓ composition on rf power when BiₓTe₁₋ₓ thin film is formed to manufacture BiₓTe₁₋ₓ single crystalline nanowire.

FIG. 10 is a graph showing X-ray diffraction patterns before and after performing heat treatment on BiTe thin film, which is manufactured using the method of present invention.

FIG. 11 illustrates processes for illustrating growth mechanism of Bi₂Te₃ single crystalline nanowire manufactured using the method of present invention.

FIG. 12 is a graph a) illustrating I-V curves at 2K and 300K of Bi₂Te₃ nanowire manufactured according to the present invention, and b) showing the relation between electric conductivity and temperature.

FIG. 13 is a schematic diagram a) illustrating a process of removing oxides from the surface of Bi single crystalline nanowire through plasma etching, and a SEM image b) illustrating Bi single crystalline nanowire after removing oxides.

FIG. 14 is a graph showing current-voltage measured after removing oxide layer from Bi single crystalline nanowire through plasma etching method.

FIG. 15 is a schematic diagram a) illustrating Bi nanowire grown sideward according to another embodiment, a SEM image b) thereof, and an I-V graph c).

FIG. 16 is a schematic diagram a) illustrating a cooling device for cooling down the substrate according to the present invention, and images b) and c) of a nanowire manufactured by the cooling device.

### BEST MODE

Hereinafter, embodiments of the present invention will be described in detail with reference to the accompanying drawings.

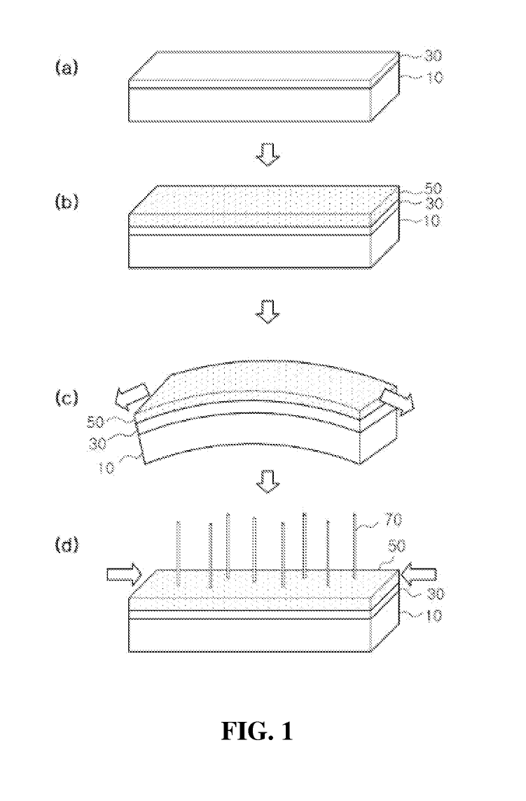

FIG. 1 is a schematic diagram illustrating the process for manufacturing single-crystalline nanowire according to present invention. Hereinafter, the method for manufacturing a nanowire according to an embodiment will be described with reference to FIG. 1. As shown in a diagram a) of FIG. 1, a substrate 10 with an oxide layer 30 formed thereon is used to manufacture single-crystalline nanowire. The substrate 10 may be thermally oxidized Si substrate having the plane of (111) direction. Preferably, the thickness of the oxide layer 30 on the substrate 10 may be 3000-5000 Å. In the present embodiment, SiO₂ is used as oxide material and the thickness of the oxide layer 30 is about 3000 Å.

Then, thin film 50 is formed on the oxide layer 30 through sputtering as shown in a diagram b) of FIG. 1. Here, it is preferable to form the thin film 50 at the thickness from 10 nm to 4 μm, which was confirmed in a plurality of experiments. In the present embodiment, the thin film 50 is formed at the thickness of 500 Å. Then, the substrate 10 with the thin film 50 formed on the oxide layer 30 is placed in a reaction chamber and heat treatment is performed thereon.

Hereinafter, the apparatus for manufacturing single-crystalline nanowire and heat treatment will be described. The apparatus includes a reaction chamber for performing heat treatment on the substrate 10 with the thin film 50 formed on the oxide layer 30.

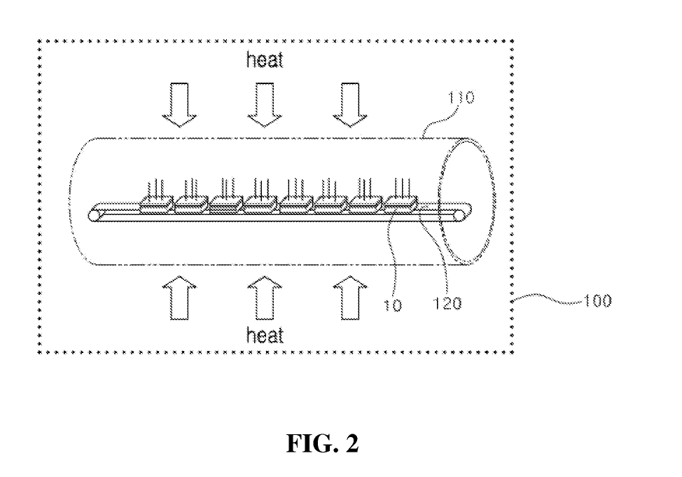

As shown in FIG. 2, the manufacturing apparatus includes a reaction chamber 100, a quartz tube 110 disposed inside the reaction chamber 100, and an alumina boat 120 disposed in the quartz tube 110. The reaction chamber 100 includes a heater (not shown). The heater heats the quartz tube 110 and the alumina boat 120 at the same time. The heating temperature can be controlled by a controller (not shown). A vacuum pump (not shown) was disposed at the right end of the quartz tube 110 to vacuumize the inside of the quartz tube 110. And the substrate 10 with the thin film 50 formed on the oxide layer 30 was placed in the alumina boat 120.

Then, the substrate 10 was heated with the alumina boat 120 by the heat generated from the heater. Here, it is preferable to maintain the inside of the reaction chamber 100 at 10⁻² Torr to 10⁻⁸ Torr. If the inside of the reaction chamber 100 is sustained below 10⁻² Torr, an oxide layer may be formed on the surface of nanowire. More preferably, the inside of the reaction chamber 100 is sustained at 10⁻⁷ Torr. By heating the substrate placed on the alumina boat 120 in vacuum state, tensile stress was induced at thin film 50 on the substrate 10 as shown in a diagram c) of FIG. 1. Since the substrate 10, the oxide layer 30, and the thin film 50 have different thermal expansion coefficients, tensile stress was applied to Bi thin film 50 having comparatively large volume expansion due to Si oxide layer 30 having small volume expansion during the heat treatment. Bi thin film 50 has thermal expansion coefficient 13.4×10⁻⁶/° C., which is larger than that of Si oxide layer 30, that is 0.5×10⁻⁶/° C. Here, heat treatment temperature of thin film 50 was about 270° C.

After finishing the heat treatment, the thin film 50 was cooled to room temperature.

At the initial stage of cooling process, compressive stress was applied to thin film 50 because the substrate and the thin film tries to deform to the original shapes. Such compressive stress operates as a thermodynamic driving force for nanowire growth in the cooling process. Here, most of single-crystalline nanowire 70 was grown as shown in a diagram d) of FIG. 2.

As described above, expanded Bi or BiₓTe₁₋ₓ thin film was contracted while the substrate with Bi or BiₓTe₁₋ₓ thin film formed on the oxide layer was cooled to room temperature after the heat treatment. Due to the contraction of the expanded Bi or BiₓTe₁₋ₓ thin film, the compressive stress operates as thermodynamic driving force and the thermodynamic driving force makes Bi or BiₓTe₁₋ₓ single crystalline nanowire growing. Accordingly, Bi or BiₓTe₁₋ₓ single crystalline nanowire was manufactured.

FIG. 6 is a schematic diagram illustrating the growth of Bi or BiₓTe₁₋ₓ single crystalline nanowire. As shown in FIG. 6, mass transportation of Bi or BiₓTe₁₋ₓ atoms are orientated to grain boundaries due to compressive stress generated by the cooling process after annealing. It becomes a seed for nanowire growth. A rough surface causes cracks to be formed at the oxide layer on Bi or BiₓTe₁₋ₓ thin film. The cracks help nanowire easily penetrate Bi or BiₓTe₁₋ₓ thin film.

In case of BiₓTe₁₋ₓ thin film instead of Bi thin film, co-sputtering was performed. The heat treatment was performed at 350° C. Here, the composition of the BiₓTe₁₋ₓ thin film can be controlled by changing rf power when Bi and Te are deposited. Since composition of BiₓTe₁₋ₓ nanowire is dependent to composition of BiₓTe₁₋ₓ thin film, BiₓTe₁₋ₓ nanowire of specific composition can be grown by controlling the composition of BₓTe₁₋ₓ thin film.

FIG. 3 is scanning electron microscopic (SEM) images of Bi and Bi₂Te₃ single crystalline nanowires, which are manufactured by using the method described above. In FIG. 3, diagram a) is the SEM image of Bi single crystalline nanowire, and diagram b) is the SEM image of a Bi₂Te₃ single crystalline nanowire. The SEM images a) and b) show that the Bi and Bi₂Te₃ single crystalline nanowires have diameter of 50 to 1000 nm and have single phase. Also, the SEM images a) and b) clearly show that the Bi and Bi₂Te₃ single crystalline nanowires are uniformly grown and the yield is high. Furthermore, the SEM images a) and b) show that the lengths of the Bi and Bi₂Te₃ single crystalline nanowires are about several hundred micrometers.

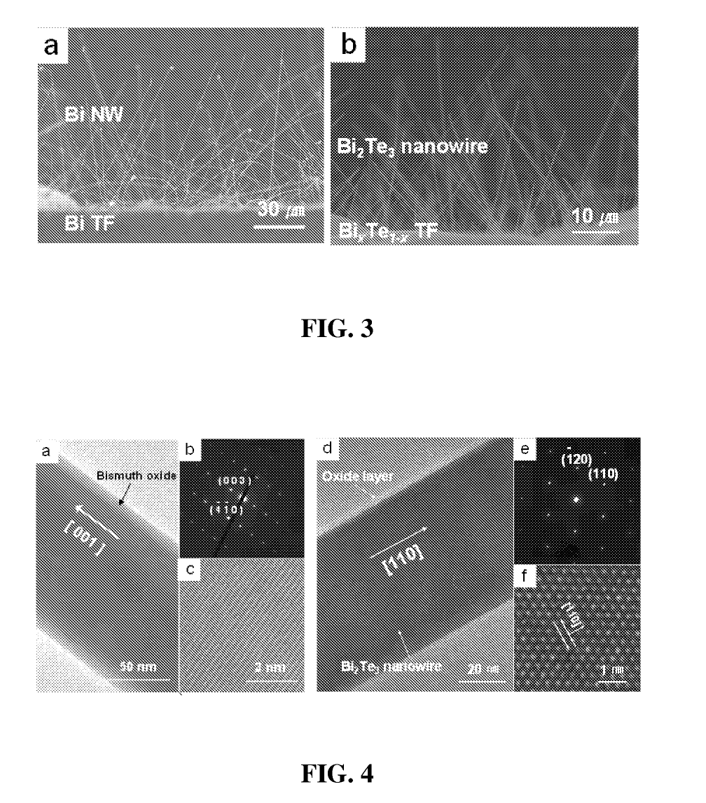

FIG. 4 is transmission electron microscopic (TEM) images and electron diffraction pattern images of Bi and Bi₂Te₃ single crystalline nanowires. Diagrams a) and d) of FIG. 4 are transmission electron microscopic (TEM) images of Bi and Bi₂Te₃ single crystalline nanowires. Diagrams b) and e) of FIG. 4 show electron diffraction patterns of Bi and Bi₂Te₃ single crystalline nanowires. The electron diffraction pattern image b) shows that a nano belt is formed along the direction [003] in a rhombohedral structure for Bi nanowire, and the electron diffraction pattern image e) shows that a nano belt is formed along the direction [110] in a rhombohedral structure for Bi₂Te₃ single crystalline nanowire. Diagrams c) and f) are high resolution TEM images of nanowires. The high resolution TEM images c) and f) show that the growth direction of Bi single crystalline nanowire is [003] direction and the growth direction of Bi₂Te₃ single crystalline nanowire is [110] direction. According to the TEM images, the second phase such as grains is not observed.

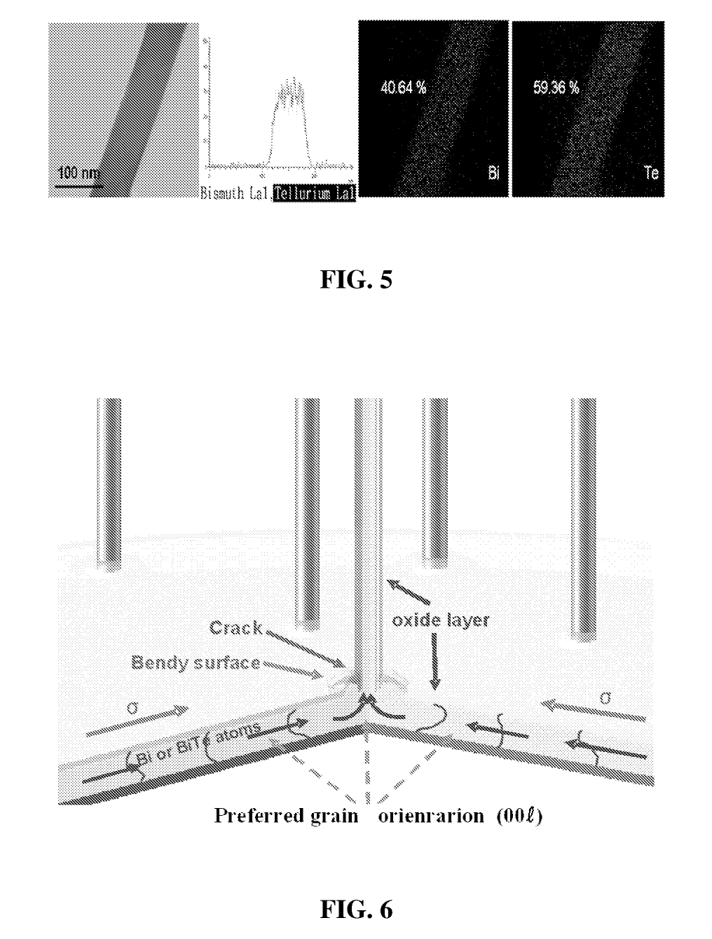

FIG. 5 is a diagram illustrating results of element mapping and line scanning for the manufactured Bi₂Te₃ single crystalline nanowire. In the graph, the blurred line denotes Bi and the solid line denotes Te. According to the element mapping result of Bi₂Te₃ single crystalline nanowire that is grown by compressive stress in cooling process from thin film grown through co-sputtering, it is confirmed that Bi and Te are uniformly distributed in the length direction of nanowire without segregation. According to a result of line scanning of Bi₂Te₃ single crystalline nanowire, it is confirmed that Bi and Te are uniformly distributed through entire nanowire.

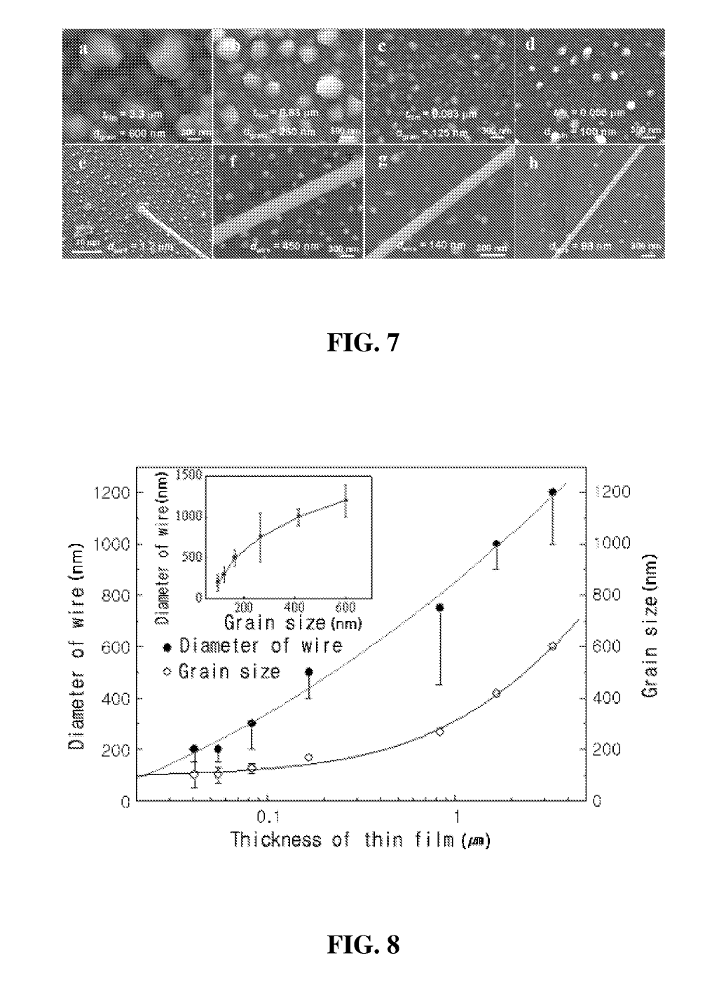

FIG. 7 is a SEM image showing the dependency of diameter to thickness of thin film in Bi nanowire, which is manufactured using the method of present invention. The diameter of nanowire became reduced from 1.2 μm to 98 nm as the size of grain decreases. In more detail, diagrams a), b), c), and d) show the surface morphology of the grown Bi thin film, and diagrams e), f), g), and h) are SEM images of Bi thin film after performing heat treatment at 270° C. for 10 hours. The diagrams a), b), c) and d) show that the thickness of thin film was controlled to 3.3 μm, 0.83 μm, 0.083 μm, and 0.055 μm, respectively. Here, the thickness of thin films, which are 3.3 μm in the diagram a), 0.83 μm in the diagram b), 0.083 μm in the diagram c), and 0.055 μm in the diagram d), are equivalent to grain sizes of 700 nm, 125 nm, 107 nm, and 100 nm. The diagrams show that the size of grain formed at thin film is reduced as the thickness of thin film decreases. The diagrams also show that straight nanowire of several hundred μm with large aspect ratio were formed after heat treatment.

Also, the diagrams show that the diameter of Bi nanowire is reduced to 1.2 μm in diagram e), 450 nm in diagram f), 140 nm in diagram g), and 98 nm in diagram h), as the size of grain is reduced to 700 nm in diagram a), 125 nm in diagram b), 107 nm in diagram c), and 100 nm in diagram d).

FIG. 8 is a graph showing dependency of diameter to thickness of thin film in Bi single crystalline nanowire, which is manufactured using the method of present invention. The graph quantitatively shows interrelation among the thickness of Bi thin film, the size of grown grain, and the size of Bi nanowire formed after heat treatment. As shown, the size of Bi nanowire is in proportion to the thickness of thin film and the size of grain. Therefore, the size of Bi nanowire depends on the size of a grain and is decided by the thickness of thin film. It means that the size of Bi nanowire may be controlled using the shown interrelation.

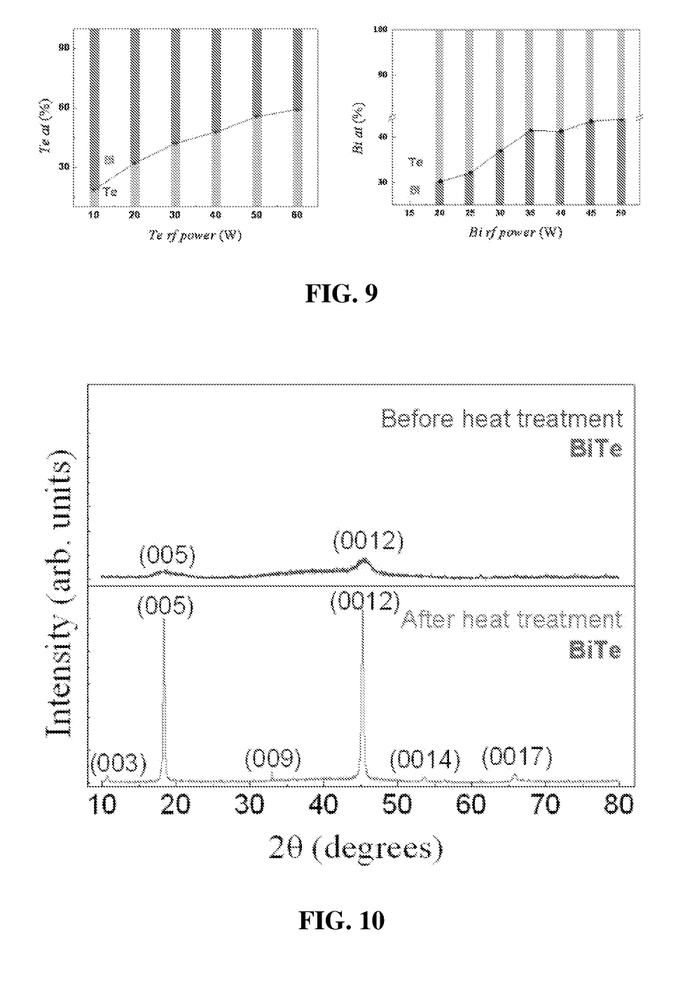

FIG. 9 is a graph showing the dependency of BiₓTe₁₋ₓ composition on rf power when BiₓTe₁₋ₓ thin film is formed to manufacture BiₓTe₁₋ₓ single crystalline nanowire. Since BiₓTe₁₋ₓ film was formed in order to manufacture BiₓTe₁₋ₓ single crystalline nanowire, the dependency of BiₓTe₁₋ₓ composition on rf power was experimented. The graph shows that the composition ratio of Bi and Te respectively depends on the power for depositing Bi and Te, when Bi and Te are co-sputtered. That is, the composition of BiₓTe₁₋ₓ can be controlled by changing depositing power when BiₓTe₁₋ₓ is deposited. Therefore, BiₓTe₁₋ₓ nanowire can be grown with the desired composition ratio.

FIG. 10 is a graph showing X-ray diffraction patterns before and after performing heat treatment on BiTe thin film, which is manufactured using the method of present invention.

As shown in the graph, crystallization is not clearly shown before the heat treatment, that is, before nanowire was grown. However, crystallization is clearly shown in a direction of (00l) plane where l is an integer number after the heat treatment, that is, after nanowire was grown.

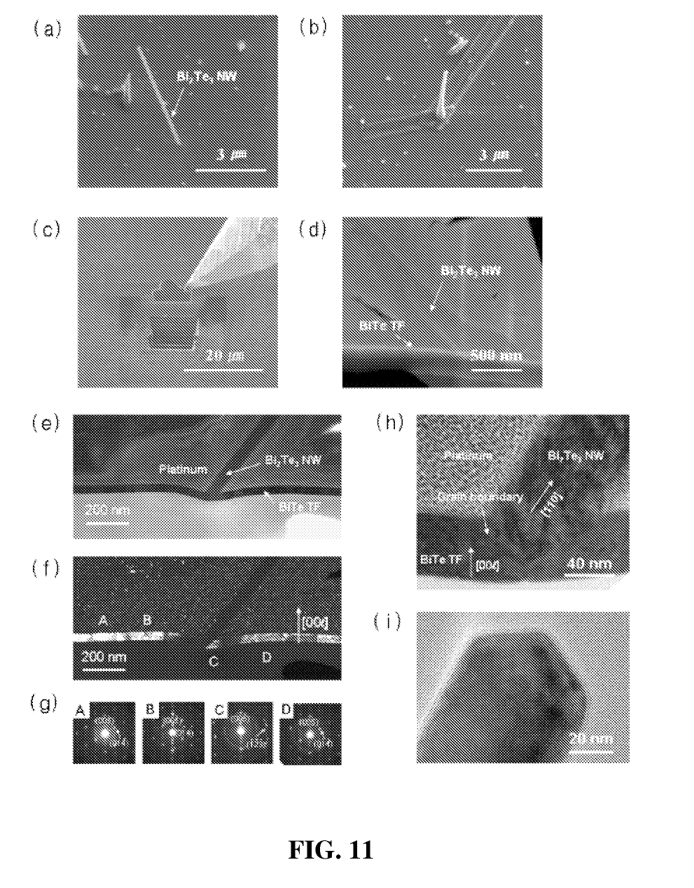

FIG. 11 illustrates processes for illustrating growth mechanism of Bi₂Te₃ single crystalline nanowire manufactured using the method of present invention.

Referring to FIG. 11, at first, Bi₂Te₃ nanowire was selected as shown in diagram a). Then, platinum passivation layer was deposited as shown in diagram b) and the thin film was vertically cut using Focused Ion Beam (FIB) method as shown in diagram d). As a result, the cross-section image of Bi₂Te₃ nanowire grown from BiTe thin film was obtained as shown in diagram e). The diagram e) is a TEM image (bright field image) of the vertical cross-section of Bi₂Te₃ nanowire grown from BiTe thin film, and diagram f) is a TEM image (dark field image) of the vertical cross-section of Bi₂Te₃ nanowire grown from BiTe thin film. Diagram g) is an electron diffraction pattern image in sections A, B, C, and D, and diagram h) is a TEM image showing BiTe thin film, and diagram i) is a TEM image illustrating the tip of grown Bi₂Te₃ nanowire.

The dark field image and diagram g) show that the crystal direction of thin film is [00l]. It is matched with the X-ray analysis.

The diagrams d) and h) of FIG. 11 also show that nanowire is grown from grain boundaries. It is also shown in the diagrams d) and h) that the composition of nanowire is Bi₂Te₃ and the composition of thin film is BiTe.

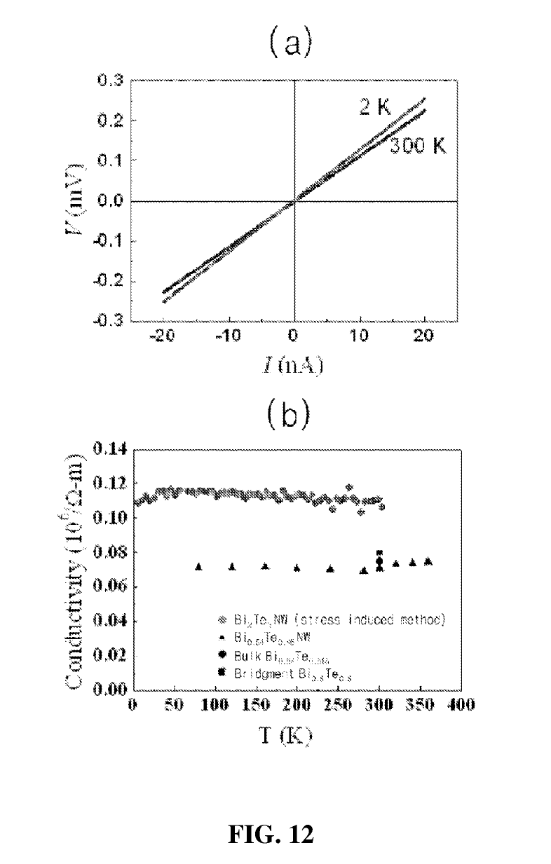

FIG. 12 is a graph a) illustrating I-V curves at 2K and 300K of Bi₂Te₃ nanowire manufactured according to the present invention, and b) showing the relation between electric conductivity and temperature. The graph a) shows that ohm contact can be formed. The graph b) shows that a Bi₂Te₃ nanowire has better electric conductivity that those of a nanowire grown by electroplating, the other composition ratio of BiTe nanowire, and bulk.

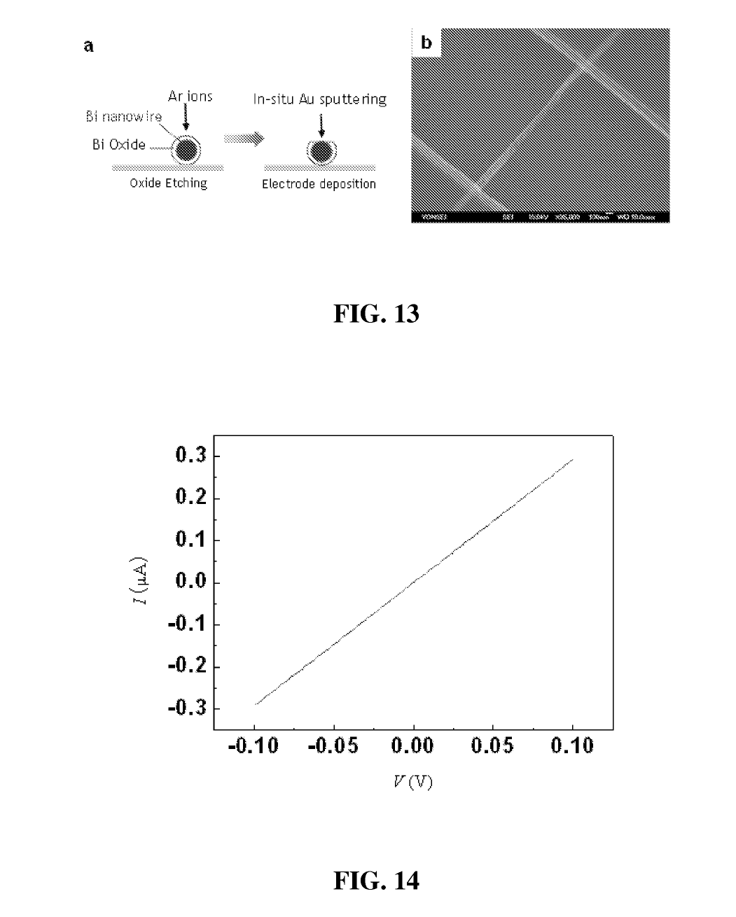

FIG. 13 is a schematic diagram a) illustrating a process of removing oxides from the surface of Bi single crystalline nanowire through plasma etching, and a SEM image b) illustrating Bi single crystalline nanowire after removing oxides. An oxide layer may be formed on the surface of grown nanowire due to oxygen in the atmosphere. In order to remove the oxide layer, Bi single crystalline nanowire was etched for 5 to 12 minutes using radio frequency (RF) plasma etching method under the conditions of 10 to 100 W of power, 2 to 3 mTorr of pressure, and 5 to 10 cm of a distance. As shown, the surface roughness of the nanowire increased after etching although the nanowire had a uniform surface before etching. It shows that the oxide layer was removed from the nanowire surface by etching the nanowire surface.

FIG. 14 is a graph showing current-voltage measured after removing oxide layer from Bi single crystalline nanowire through plasma etching method. Ohmic contact is confirmed from the current-voltage graph. It means that the oxide layer was removed from the surface of nanowire.

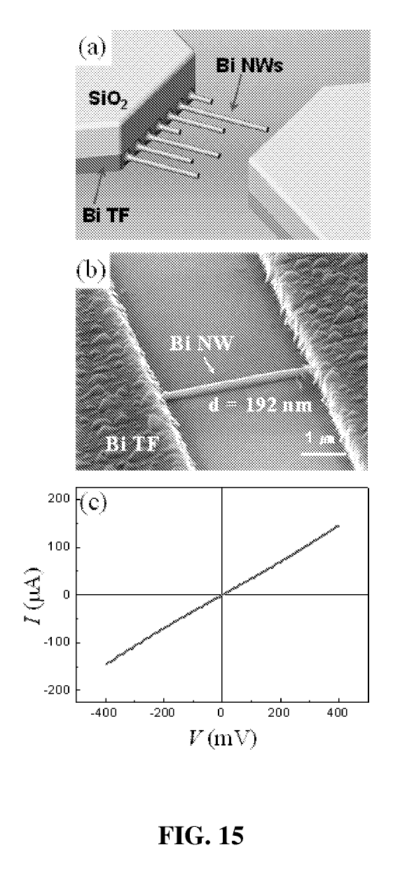

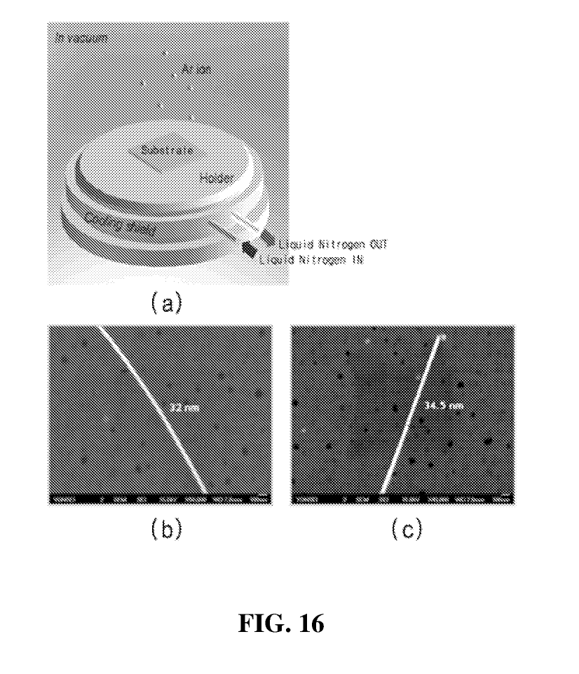

FIG. 15 is a schematic diagram illustrating Bi nanowire grown sideward according to another embodiment, a SEM image b) thereof, and an I-V graph c). In the present embodiment, SiO₂ thin film is sputtered on Bi thin film. In this case, Bi nanowire cannot be grown upward from Bi thin film due to SiO₂ thin film as shown in diagram a). Accordingly Bi nanowire was grown sideward in order to release compressive stress. The SEM image b) clearly shows Bi nanowire grown sideward. The sideward grown Bi nanowire was coupled to an electrode at the opposite side before the oxide layer was formed. Therefore, the sideward grown Bi nanowire can be used as a device without performing oxide layer removing process and an electrode forming process. It can be confirmed based on the I-V measuring data shown in the graph c) of FIG. 15.

FIG. 16 is a schematic diagram a) illustrating a cooling device for cooling down the substrate according to the present invention, and images b) and c) of a nanowire manufactured by the cooling device. As shown in diagram a) of FIG. 16, the cooling device cooled down the substrate by coolant flowing inside the holder where the substrate is put thereon. Although any coolant may be used, liquid nitrogen was used in the present embodiment. Liquid nitrogen cooled down the substrate to −200° C. If deposition is performed under this condition, the grain size of thin film formed on the substrate becomes smaller. If the grain size is small, the diameter of nanowire grown through heat treatment becomes smaller too. That is, the nanowire with 32 nm or 34.5 nm of diameter was obtained as shown in the images b) and c) of FIG. 16. That is, the diagram a) and the images b) and c) show that it is possible to control the shape of nanowire by controlling the temperature of substrate when deposition is performed.

1. A method for manufacturing a nanowire using a compressive stress, comprising:
providing a substrate with an intermediate layer formed thereon;
forming thin film on the intermediate layer, wherein the thin film made of material having more than 2×10⁻⁶/° C. of thermal expansion coefficient difference from the intermediate layer;
inducing tensile stress due to the thermal expansion coefficient difference between the thin film and the substrate by performing a heat treatment on the substrate with the thin film formed; and
growing single-crystalline nanowire of the material by inducing compressive stress at the thin film through cooling of the substrate.

2. The method of claim 1, wherein the material forming the thin film is Bi.

3. The method of claim 1, wherein the thin film is deposited by sputtering.

4. The method of claim 1, wherein the material forming the thin film is BiₓA₁₋ₓ, where A is one of Te, Se, and Sb.

5. The method of claim 4, wherein x is about 0.33 to 0.55.

6. The method of claim 5, wherein x is 0.4 and the material is Bi₂Te₃.

7. The method of claim 1, wherein the thickness of thin film is 10 nm to 4 μm.

8. The method of claim 1, wherein the substrate is Si substrate.

9. The method of claim 1, wherein the intermediate layer is an oxide layer.

10. The method of claim 9, wherein the oxide is one of SiO₂, Al₂O₃, BeO, and Mg₂A₁₄Si₅O₁₈.

11. The method of claim 1, further comprising:
removing the oxide layer formed on the surface of nanowire.

12. The method of claim 11, wherein the oxide layer is removed by plasma etching.

13. The method of claim 12, wherein the plasma etching is performed for 5 to 12 minutes with conditions of 10 to 100 W of power, 2 to 3 mTorr of pressure, and 5 to 10 cm of distance.

14. The method of claim 1, wherein the heat treatment is performed at 100 to 1000° C.

15. The method of claim 1, wherein the heat treatment is performed for 0.5 to 15 hours.

16. The method of claim 1, wherein the diameter of the nanowire is 32 to 1000 nm.

17. The method of claim 1, further comprising:
forming a barrier layer on the thin film for preventing nanowire from being grown to upward direction from the thin film.

18. The method of claim 17, wherein the barrier layer is made of SiO₂, Cr, or W.

19. The method of claim 1, wherein the thin film orients in a direction of (00l) plane where l is an integer number.

20. The method of claim 1, wherein the thin film is formed on the substrate after cooling the substrate for the refinement of grains in the thin film.

21. A method for manufacturing a nanowire using compressive stress, comprising:
providing a substrate;
forming thin film on the substrate, wherein the film is made of material having more than 2×10⁻⁶/° C. of thermal expansion coefficient difference from the substrate;
inducing tensile stress due to the thermal expansion coefficient difference between the thin film and the substrate by performing heat treatment on the substrate with the thin film formed; and
growing single crystalline nanowire of the material by inducing compressive stress at the thin film by cooling down the substrate.

22. The method of claim 2, wherein the thin film is deposited by sputtering.
